(19) United States
(12) Patent Application Publication
(10) Pub. No.: US 2021/0376296 A1
(43) Pub. Date: Dec. 2, 2021

(54) PREPARATION METHOD OF DISPLAY PANEL, DISPLAY PANEL AND DISPLAY DEVICE

(71) Applicants: Chengdu BOE Optoelectronics Technology Co., Ltd., Chengdu, Sichuan Province (CN); BOE Technology Group Co., Ltd., Beijing (CN)

(72) Inventors: Wenwei MO, Beijing (CN); Kunlong ZHENG, Beijing (CN); Pengsha MA, Beijing (CN)

(21) Appl. No.: 16/768,118

(22) PCT Filed: Dec. 16, 2019
(86) PCT No.: PCT/CN2019/125759

§ 371 Date: May 29, 2020

(30) Foreign Application Priority Data
Jan. 9, 2019 (CN) 201910018945.9

(51) Int. Cl. H01L 51/52; H01L 51/56

(52) U.S. Cl. CPC H01L 51/5284; H01L 2251/5338; H01L 51/56

(57) ABSTRACT

The present disclosure provides a preparation method of a display panel, a display panel and a display device, used for solving the problem of poor effect of removing parts, in bending areas, of back film in the prior art. The preparation method of a display panel includes: attaching a whole-face back film to the back surface of a display substrate, wherein the back film is provided with a continuous pattern covering a display area and a non-display area of the display substrate; shielding the part, in a bending area of the non-display area, of the back film by a first shielding part on the side, away from the display substrate, of the back film, and then irradiating the back film with ultraviolet light so as to adhere the back film excluding the part in the bending area to the display substrate; and removing the part, in the bending area, of the back film.

The present disclosure is a National Stage of International Application No. PCT/CN2019/125759, filed on Dec. 16, 2019, which claims the priority to the Chinese Patent Application No. 201910018945.9, filed with the Chinese Patent Office on Jan. 9, 2019, both of which are hereby incorporated by reference in their entireties.

### FIELD

The present disclosure relates to the field of liquid crystal display technologies, and particularly to a preparation method of a display panel, a display panel, and a display device.

### BACKGROUND

With the rapid development of active-matrix organic light-emitting diodes (AMOLED) and full-screen technology, it is necessary to achieve narrow bezel and higher screen-to-body ratio of displays. In displays, a polarizer (POL), a Panel, a back film and other components are stuck together, and in order to achieve a higher screen-to-body ratio, the Panel needs to be bent at its Pad end, i.e., the end connected to an external circuit.

Taking a flexible organic light-emitting diode (OLED) as an example, in the preparation process of a display panel, after an OLED device is fabricated on a flexible substrate, the OLED device is thin-film encapsulated, and a protective film is attached to the whole back surface of the flexible substrate. In order to bend the Panel at its the Pad end conveniently, the back film located in a bending area is peeled off.

### SUMMARY

In a first aspect, embodiments of the present disclosure provide a preparation method of a display panel, the method includes:

attaching a whole-face back film to a back surface of a display substrate, wherein the back film is provided with a continuous pattern covering a display area and a non-display area of the display substrate;

shielding a part, in a bending area of the non-display area, of the back film by a first shielding part on a side, away from the display substrate, of the back film, and then irradiating the back film with ultraviolet light so as to adhere the back film excluding the part in the bending area to the display substrate; and removing the part, in the bending area of the non-display area, of the back film.

In a possible implementation manner, the step of removing the part, in the bending area of the non-display area, of the back film specifically includes:

adhering a carrier film to a face, away from the display substrate, of the back film;

shielding a part, in the bending area of the non-display area, of the carrier film by a second shielding part on the side, away from the back film, of the carrier film, and then irradiating the carrier film with ultraviolet light so as to remove the carrier film excluding the part in the bending area of the carrier film from the back film; and

removing the carrier film so as to remove the part, in the bending area of the non-display area, of the back film, and adhered to the carrier film.

In a possible implementation manner, the step of removing the carrier film includes: fixing the part, in the bending area of the non-display area, of the back film and the carrier film by a clamp; and removing the carrier film and the part, in the bending area of the non-display area, of the back film simultaneously by the clamp.

In a possible implementation manner, the step of shielding the part, in the bending area of the non-display area, of the back film by the first shielding part specifically includes:

shielding the back film by a first mask with a shielding pattern in the bending area of the non-display area; or

preparing a light-shielding film for shielding the bending area of the non-display area on the face, away from the display substrate, of the back film.

In a possible implementation manner, the step of shielding the part, in the bending area of the non-display area, of the carrier film by a second shielding part specifically includes:

shielding the carrier film by a second mask with a shielding pattern in the bending area of the non-display area; or

preparing a light-shielding film for shielding the bending area of the non-display area on the face, away from the display substrate, of the carrier film.

In a possible implementation manner, the first mask and the second mask are the same mask.

In a possible implementation manner, after removing the part, in the bending area of the non-display area, of the back film, the method further includes:

bending the display substrate backwards along the bending area of the non-display area.

In a second aspect, embodiments of the present disclosure provide a display panel prepared by adopting the preparation method described in the first aspect. The display panel includes: a display substrate and a back film, wherein,

the display substrate includes a display area and a non-display area, and the non-display area includes a bending area; and

the back film is adhered to the back surface of the display substrate, and the back film is not provided with a pattern in the bending area.

In a possible implementation manner, the back film is made from an ultraviolet-curable material.

In a third aspect, embodiments of the present disclosure provide a display device including the display panel described in the second aspect.

### BRIEF DESCRIPTION OF THE DRAWINGS

FIG. 1 is a flowchart of a preparation method of a display panel according to the embodiment of the present disclosure.

FIG. 2 is a schematic structural diagram of a display panel according to the embodiment of the present disclosure.

FIG. 3 is a schematic structural diagram of back film shielding in a bending area of a display panel according to the embodiment of the present disclosure.

FIG. 4 is a schematic structural diagram of back film shielding in a bending area of a display panel according to the embodiment of the present disclosure.

FIG. 5 is a schematic structural diagram of a carrier film according to an embodiment of the present disclosure.

FIG. 6 is a schematic structural diagram of a display panel according to the embodiment of the present disclosure.

### DETAILED DESCRIPTION OF THE EMBODIMENTS

At present, in the preparation process of display panels, there are various methods for peeling off back film in bending areas. For example, adhere to each display panel with a roller to remove the back film in the bending areas, or laser is adopted to peel the back film in the bending areas. If the method of roller adhesion is adopted, since the width of the bending areas is relatively small, it is difficult to remove the back film in the bending areas, and the efficiency is low. If laser is adopted to peel off the back film in the bending areas, dust particles which are liable to be produced by laser burning causes damage to circuits, in addition, in order to prevent laser from damaging packaging films on substrates during the laser burning process, the back film are partially peeled off usually, then the back film in the bending areas are thick, and bending is not facilitated. Therefore, the effect of removing the back film in the bending areas in the prior art is poor.

To make the objectives, technical solutions and advantages of the present disclosure clearer, the technical solutions in the embodiments of the present disclosure will be described clearly and completely below in conjunction with the drawings in the embodiments of the present disclosure.

The present disclosure provides a preparation method of a display panel, a display panel and a display device, which are used for reducing the adhesion between a back film in a bending area and a display substrate, improving the effect of removing the back film in the bending area, and further improving the product quality.

The specific implementation of a preparation method of a display panel, a display panel and a display device provided by embodiments of the present disclosure will be described in detail below in conjunction with the accompanying drawings.

The thickness and shape of each film layer in the drawings do not reflect the true ratios, but are only used to illustrate the present disclosure.

Referring to FIG. 1, a preparation method of a display panel provided by an embodiment of the present disclosure is specifically described as follows.

Step 101, attaching a whole-face back film to a back surface of a display substrate, wherein the back film covers a display area and a non-display area of the display substrate.

In the embodiment of the present disclosure, before preparation of the display panel, the back film may be prepared. Specifically, a pressure-sensitive adhesive may be bonded to the substrate, then a protective film may be formed on the side, away from the display substrate of the pressure-sensitive adhesive layer. The protective film may be made from polymer materials such as polyimide film (PI) or polyethylene terephthalate (PET). After forming the pressure-sensitive adhesive layer and the protective film stacked on each other, the substrate can be removed to form a back film, and the back film which can be bonded on the display substrate is obtained after being treated, wherein the back film may be made from an ultraviolet-curable material.

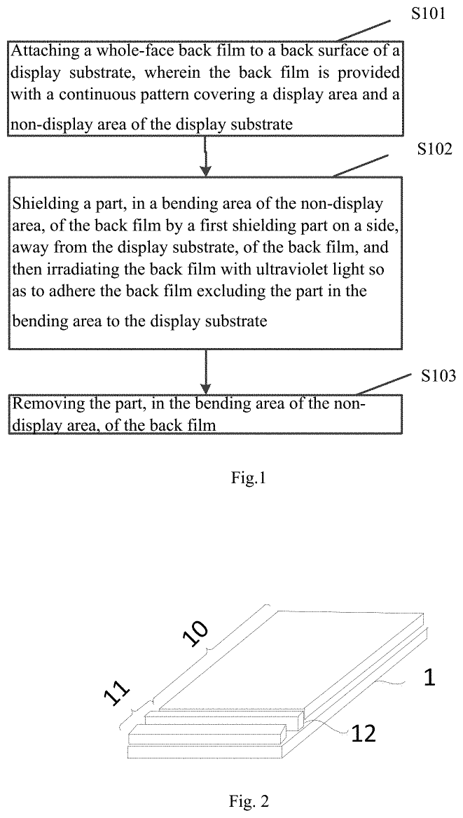

For easy understanding, the display substrate 1 including a display area 10 and a non-display area 11 and the non-display area 11 including a bending area 12 are taken as an example below to explain how to process the back film 2 in conjunction with FIGS. 2 to 5.

Referring to FIG. 2, a continuous pattern covering the display area 10 and the non-display area 11 is formed on the back film 2, thereby the back film 2 provided with the continuous pattern covering the display area 10 and the non-display area 11 is obtained, and then the whole-face back film 2 is attached to the back surface of the display substrate 1.

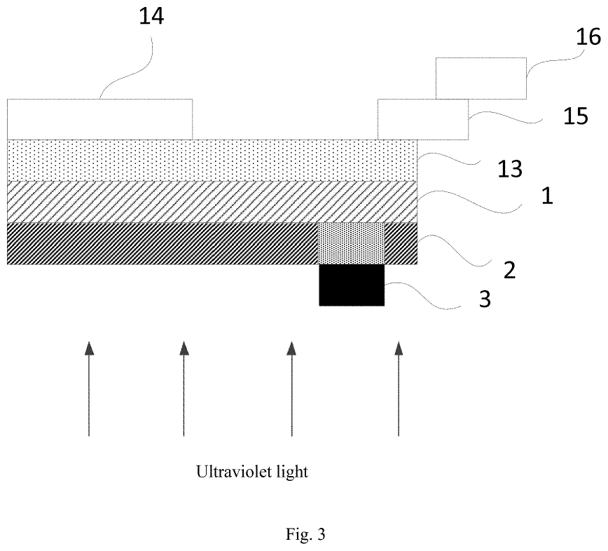

Referring to FIG. 3, after the back film 2 is attached to the back surface of the display substrate 1, a light-emitting layer 13 may further be arranged on the front surface of the display substrate 1, a polarizer 14 is arranged on the face, away from the display substrate 1, of the light-emitting layer 13 and is located in the display area, a chip on film 15 (COF) is bound to the non-display area, and then a flexible printed circuit 16 (FPC) is bound to the chip on film 15 (COF). In the embodiment of the present disclosure, the specific binding method of the COF and the FPC is similar to that in the prior art, which is not limited here.

Step 102: shielding a part, in a bending area of the non-display area, of the back film by a first shielding part on a side, away from the display substrate, of the back film, and then irradiating the back film with ultraviolet light so as to adhere the back film excluding the part in the bending area to the display substrate.

As shown in FIG. 3, after the back film 2 is attached to the back surface of the display substrate 1, the first shielding part 3 may be arranged on the side, away from the display substrate 1, of the back film 2, so that the first shielding part 3 shields the part, in the bending area 12 of the non-display area 11, of the back film 2, wherein the first shielding part 3 may be a first mask with a shielding pattern in the bending area, or may be a light-shielding film.

If the first shielding part 3 is a light-shielding film, as shown in FIG. 3, the light-shielding film is attached to the part, in the bending area, of the back film for shielding the bending area. The light-shielding film is made from a polyethylene film, a polypropylene film, a polyvinyl chloride film, a polyester film or other materials. The material of the light-shielding film is not limited here, as long as the light-shielding film is light-proof.

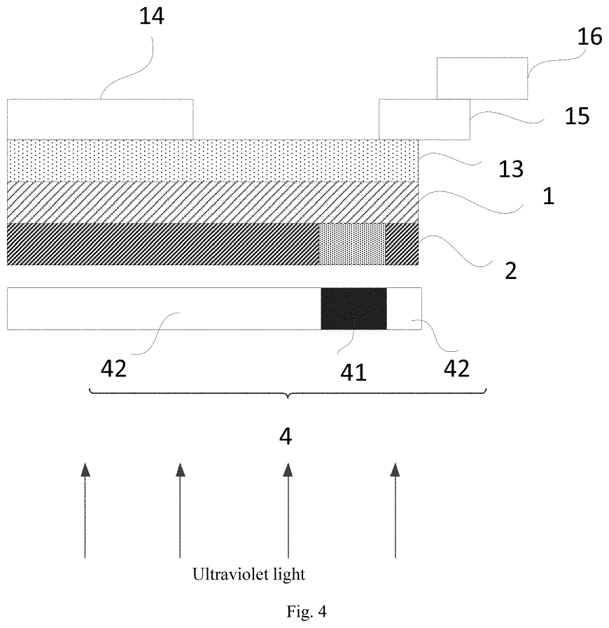

If the first shielding part 3 is a first mask 4, as shown in FIG. 4, the first mask 4 is on the side, away from the display substrate 1, of the back film 2, and the first mask 4 includes a shielding area 41 and a transparent area 42, wherein the transparent area 42 is used for transmitting ultraviolet light, and the shielding area 41 is used for shielding the part, in the bending area 12, of the back film. When ultraviolet light irradiates the first mask 4, the transparent area 42 can transmit the ultraviolet light, so that the ultraviolet light irradiates the back film excluding the part, in the bending area 12, of the back film, while the part, in the bending area 12, of the back film cannot be irradiated by ultraviolet light due to the shielding of the shielding area 41.

After the part, in the bending area 12 of the non-display area, of the back film 2 is shielded by the first shielding part 3, the back film 2 is irradiated by ultraviolet light. Since the back film 2 is made from an ultraviolet-curable material, when ultraviolet light irradiates the back film 2, the part, not shielded by the first shielding part 3, of the back film 2 is cured and adhered to the display substrate 1.

Step 103, removing the part, in the bending area of the non-display area, of the back film.

After the back film 2 is attached to the back surface of the display panel 1, a carrier film 5 is adhered to a face, away from the display substrate 1, of the back film 2; after the part, in the bending area 12, of the carrier film 5 is shielded by a second shielding part 6 on the side, away from the back film 2, of the carrier film 5, the carrier film 5 is irradiated by ultraviolet light, so that the carrier film 5 excluding the part, in the bending area 12, of the carrier film, is removed from the back film 2, the carrier film 5 is removed for removing the part, located in the bending area 12, of the back film 2, and adhered to the carrier film 5, at least the part, in the bending area 12, of the back film 2 can be removed, it is ensured that there are as few parts of the back film 2 as possible in the bending area 12 for facilitating bending of the bending area 12 of the display panel 1, and the screen-to-body ratio of a display is increased.

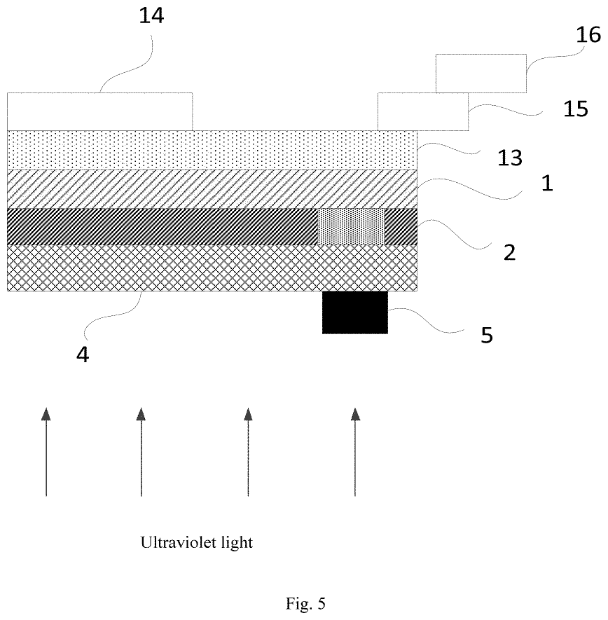

Specifically, referring to FIG. 5, a carrier film 5 is adhered to the face, away from the display substrate 1, of the back film 2. The carrier film 5 is made from an ultraviolet-curable material which is a peelable material, for example, a photo-curable organosilicon material is adopted as a release material, or an epoxy-terminated polysiloxane ultraviolet curing system material. Then, a second shielding part 6 is arranged on the side, away from the back film 2, of the carrier film 5, wherein the second shielding part 6 may be a second mask with a shielding pattern, the second mask may be the same mask as the first mask for shielding the back film 2 or may be a different mask, which is not limited here, and the second shielding part 6 may also be a light-shielding film attached to the face, away from the display substrate 1, of the carrier film 5. After the second shielding part 6 is arranged, the part, in the bending area 12, of the carrier film 5 is shielded by the second shielding part 6, and after shielding, ultraviolet light is adopted for irradiating the carrier film 5, since the carrier film 5 is made from the ultraviolet-curable peelable material, after the ultraviolet light irradiates the carrier film 5, the carrier film 5 excluding the part in the bending area, of the carrier film can be separated from the back film 2, the part, in the bending area 12, of the back film is adhered to the carrier film 5, the carrier film 5 is removed, and then the part, located in the bending area 12, of the back film 2 and adhered to the carrier film 5 is removed. In order to ensure that the part, in the bending area 12, of the back film can be effectively removed, the part, in the bending area 12, of the back film and the carrier film 5 can be fixed by a clamp, and the carrier film 5 and the part, in the bending area 12, of the back film are simultaneously removed by the clamp.

In the embodiment of the present disclosure, in the preparation process of the display panel, after the part, in the bending area 12 of the non-display area, of the back film 2 is shielded by the first shielding part 3 on the side, away from the display substrate 1, of the back film 2, the back film 2 is irradiated by ultraviolet light, then the carrier film 5 is adhered to the face, away from the display substrate 1, of the back film 2. After the part, in the bending area 12, of the carrier film 5 is shielded by the second shielding part 6 on the side, away from the back film 2, of the carrier film 5, the carrier film 5 is irradiated by ultraviolet light, so that the carrier film 5 excluding the part in the bending area 12 of the carrier film 5 is removed from the back film 2, and thus the part, located in the bending area 12, of the back film 2 and adhered to the carrier film 5 is removed. Therefore, by removing the carrier film 5 to remove the part, located in the bending area 12, of the back film 2 and adhered to the carrier film 5, the difficulty of removing the part, in the bending area 12, of the back film is reduced, and the adhesion between the part, in the bending area 12, of the back film and the display substrate 1 is reduced, the effect of removing the part, in the bending area 12, of the back film is improved, and the product quality is further improved.

Further, after removing the part, in the bending area 12, of the back film 2, the method further includes: bending the display substrate 1 backwards along the bending area 12.

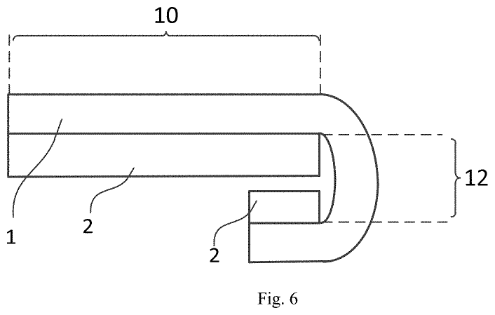

Referring to FIG. 6, in the embodiments of the present disclosure, after the part, in the bending area 12, of the back film 2 is removed, the display panel 1 is bent backwards along the bending area 12 to form a display panel. Since the display panel 1 is bent backwards along the bending area 12, the non-display area 11 is actually invisible, and is indicated by a dotted line in FIG. 6.

Based on the same inventive concept, the embodiments of the present disclosure also provide a display panel prepared by adopting the above preparation method. Since the problem solving principle of the display panel is similar to that of the above-mentioned preparation method, the implementation of the display panel may refer to implementation of the preparation method, and details are not repeated here.

Referring to FIGS. 2 to 5, the display panel includes: a display substrate 1 and a back film 2.

The display substrate 1 includes a display area 10 and a non-display area 11, and the non-display area 11 includes a bending area 12.

The back film 2 is adhered to the back surface of the display substrate 1, and the back film 2 is not provided with a pattern in the bending area 12.

Specifically, the back film 2 is made from an ultraviolet-curable material.

It should be noted that, since the flexible display panel in the embodiments of the present disclosure is bent without a part, in the bending area, of the back film, stress on the bending area of the flexible display panel during bending can be reduced, the difficulty of bending the flexible display panel in the bending area is reduced, and the product quality is improved.

Based on the same inventive concept, embodiments of the present disclosure further provide a display device, including the above display panel provided by the embodiments of the present disclosure. The display device may be any product or component with a display function, such as a mobile phone, a tablet computer, a television, a display, a notebook computer, a digital photo frame and a navigator. The implementation of the display device may refer to the above embodiments of the flexible display panel, and details are not repeated here.

Obviously, those skilled in the art can make various modifications and variations to the present disclosure without departing from the spirit and scope of the present disclosure. In this way, if these modifications and variations of the present disclosure fall within the scope of the claims of the present disclosure and equivalent technologies thereof, the present disclosure is also intended to include these modifications and variations.

1. A preparation method of a display panel, comprising:
attaching a whole-face back film to a back surface of a display substrate, wherein the back film is provided with a continuous pattern covering a display area and a non-display area of the display substrate;
shielding a part, in a bending area of the non-display area, of the back film by a first shielding part on a side, away from the display substrate, of the back film, and then irradiating the back film with ultraviolet light so as to adhere the back film excluding the part in the bending area to the display substrate; and
removing the part, in the bending area of the non-display area, of the back film.

2. The preparation method according to claim 1, wherein the step of removing the part, in the bending area of the non-display area, of the back film specifically comprises:
adhering a carrier film to a face, away from the display substrate, of the back film;
shielding a part, in the bending area of the non-display area, of the carrier film by a second shielding part on a side, away from the back film, of the carrier film, and then irradiating the carrier film with ultraviolet light so as to remove the carrier film excluding the part, in the bending area, of the carrier film from the back film; and
removing the carrier film so as to remove the part, in the bending area of the non-display area, of the back film, and adhered to the carrier film.

3. The preparation method according to claim 2, wherein the step of removing the carrier film comprises:
fixing the part, in the bending area of the non-display area, of the back film and the carrier film by a clamp; and
removing the carrier film and the part, in the bending area of the non-display area, of the back film simultaneously by the clamp.

4. The preparation method according to claim 3, wherein the step of shielding the part, in the bending area of the non-display area, of the back film by the first shielding part specifically comprises:
shielding the back film by a first mask with a shielding pattern in the bending area of the non-display area; or
preparing a light-shielding film for shielding the bending area of the non-display area on the face, away from the display substrate, of the back film.

5. The preparation method according to claim 4, wherein the step of shielding the part, in the bending area of the non-display area, of the carrier film by a second shielding part specifically comprises:
shielding the carrier film by a second mask with a shielding pattern in the bending area of the non-display area; or
preparing a light-shielding film for shielding the bending area of the non-display area on the face, away from the display substrate, of the carrier film.

6. The preparation method according to claim 5, wherein the first mask and the second mask are the same mask.

7. The preparation method according to claim 1, wherein after removing the part, in the bending area of the non-display area, of the back film, the method further comprises:
bending the display substrate backwards along the bending area of the non-display area.

8. A display panel prepared by adopting the preparation method according to claim 1, comprising: a display substrate and a back film, wherein,
the display substrate comprises a display area and a non-display area, and the non-display area comprises a bending area; and
the back film is adhered to the back surface of the display substrate, and the back film is not provided with a pattern in the bending area.

9. The display panel according to claim 8, wherein the back film is made from an ultraviolet-curable material.

10. A display device, comprising the display panel according to claim 8.
